(19) United States
(12) Patent Application Publication
(10) Pub. No.: US 2026/0059671 A1
(43) Pub. Date: Feb. 26, 2026

(54) NOISE REDUCTION APPARATUS OF ELECTRONIC BRAKE DEVICE FOR VEHICLE

(71) Applicant: HYUNDAI MOBIS CO., LTD., Seoul (KR)

(72) Inventor: Si Yoon PARK, Yongin-si (KR)

(73) Assignee: HYUNDAI MOBIS CO., LTD., Seoul (KR)

(21) Appl. No.: 19/089,826

(22) Filed: Mar. 25, 2025

(30) Foreign Application Priority Data
Aug. 23, 2024 (KR) 10-2024-0113877

(51) Int. Cl. H05K 5/00

(52) U.S. Cl. CPC H05K 5/0056; H05K 5/006

(57) ABSTRACT

A noise reduction device includes a housing, a printed circuit board (PCB) part installed in the housing and including circuit devices disposed thereon, and a fastening part configured to fasten the PCB part to the housing to reduce vibration of the PCB part.

### CROSS-REFERENCE TO RELATED APPLICATION

This application claims priority from and the benefit under 35 USC § 119 of Korean Patent Application No. 10-2024-0113877, filed on Aug. 23, 2024, in the Korean Intellectual Property Office, the entire disclosure of which is incorporated by reference for all purposes.

### BACKGROUND

### 1. Technical Field

Exemplary embodiments of the present disclosure relate to a noise reduction apparatus of an electronic brake device for a vehicle, and more particularly, to a noise reduction apparatus of an electronic brake device for a vehicle, capable of reducing vibration and noise generated from circuit devices mounted on a printed circuit board (PCB).

### 2. Description of the Related Art

An integrated regenerative brake device for a vehicle is structured to operate a motor to generate hydraulic pressure to generate a braking force required by a driver. In this process, the behavior stability of the vehicle is secured through electronic control by efficiently supplying current through an electronic control unit (ECU).

However, a large number of circuit devices called multilayer ceramic capacitors (MLCCs) are used to assist current supply, and the circuit devices generate vibrations and radiate high-frequency noise through the PCB. Therefore, there is a need to improve such phenomenon.

The background technology of the present disclosure is disclosed in Korean Patent Publication No. 10-2016-0057106 (published on May 23, 2016, entitled “NOISE REDUCTION APPARATUS OF PRINTED CIRCUIT BOARD”).

### SUMMARY

Various embodiments are directed to a noise reduction apparatus of an electronic brake device for a vehicle, which can reduce vibration and noise generated from circuit devices mounted on a printed circuit board (PCB).

In an embodiment of the present disclosure, a noise reduction apparatus of an electronic brake device for a vehicle may include a housing, a printed circuit board (PCB) part installed in the housing and including circuit devices disposed thereon, and a fastening part configured to fasten the PCB part to the housing to reduce vibration of the PCB part.

The housing may include a housing body configured to accommodate the PCB part, and housing inner protrusions protruding on an inner surface of the housing body and in contact with an edge portion of the PCB part.

A plurality of housing inner protrusions may be disposed on an inner surface of the housing body at an equal interval.

The edge portion of the PCB part may be press-fitted to the housing inner protrusions.

The fastening part may include bolts inserted into the PCB part and the housing body, nuts coupled to an end of each of the bolts exposed to the outside of the housing body, and spacers interposed between the PCB part and the housing body to separate the PCB part and the housing body from each other.

Each of the spacers may be formed in a hollow shape and the bolt may be inserted into the spacers.

The spacers may be elastically deformable to absorb the vibration of the PCB part.

The nuts may be screw-fastened to the end of each of the bolts.

A head of each of the bolts may be in close contact with the PCB part.

The nuts may be in close contact with the housing body.

The noise reduction device may further include a cover part configured to cover the PCB part and close the open housing.

The cover part may include a material that shields vibration noise of circuit elements of the PCB part.

According to the noise reduction apparatus of an electronic brake device for a vehicle according to the present disclosure, by reducing vibration noise generated from multiple circuit devices mounted on a PCB, discomfort caused by the vibration noise to passengers riding in the vehicle can be reduced.

According to the present disclosure, vibration noise generated from an electronic brake can be reduced, thereby preventing quality deterioration.

### BRIEF DESCRIPTION OF THE DRAWINGS

FIG. 1 is a perspective view schematically illustrating a noise reduction apparatus of an electronic brake device for a vehicle according to an embodiment of the present disclosure.

FIG. 2 is an exploded perspective view schematically illustrating a noise reduction apparatus of an electronic brake device for a vehicle according to an embodiment of the present disclosure.

FIG. 3 is a cross-sectional view taken along line A-A of FIG. 1.

FIG. 4 is a partially enlarged cross-sectional view of region “B” of FIG. 3.

FIG. 5 is a perspective view schematically illustrating a state in which a cover part is removed from a noise reduction apparatus of an electronic brake for a vehicle according to an embodiment of the present disclosure.

FIG. 6 is a plan view schematically illustrating a state in which a cover part is removed from a noise reduction apparatus of an electronic brake for a vehicle according to an embodiment of the present disclosure.

### DETAILED DESCRIPTION

Hereinafter, a noise reduction apparatus of an electronic brake device for a vehicle according to the present disclosure will be described in detail below with reference to the accompanying drawings through various exemplary embodiments. It should be considered that the thickness of each line or the size of each component in the drawings may be exaggeratedly illustrated for clarity and convenience of description.

In addition, terms to be described below have been defined by taking into consideration their functions in the present disclosure, and may be different depending on a user or operator's intention or practice. Accordingly, such terms should be interpreted based on the overall contents of this specification.

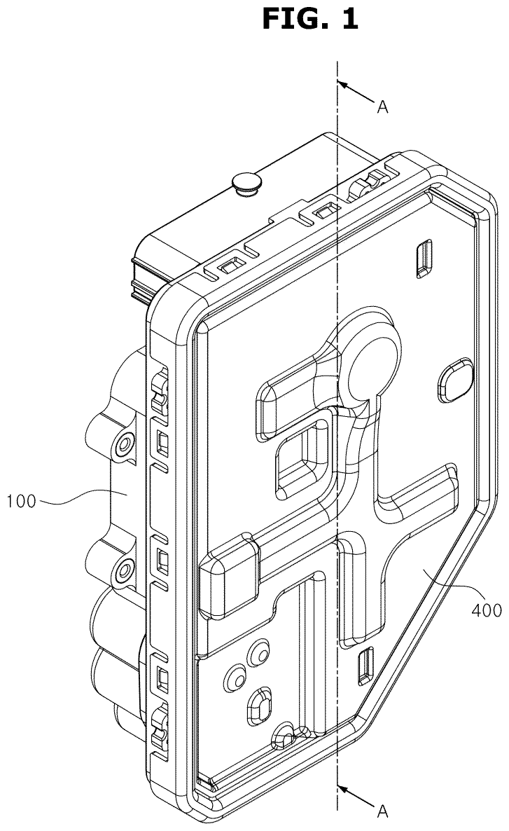

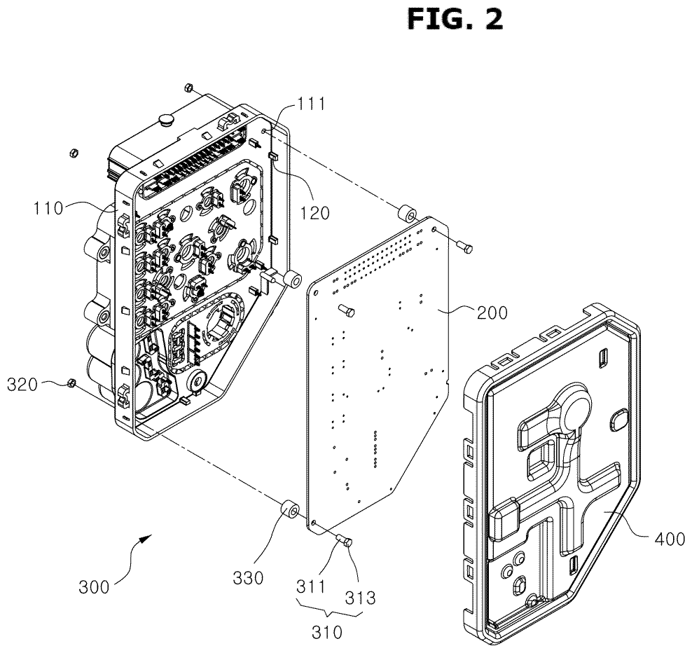

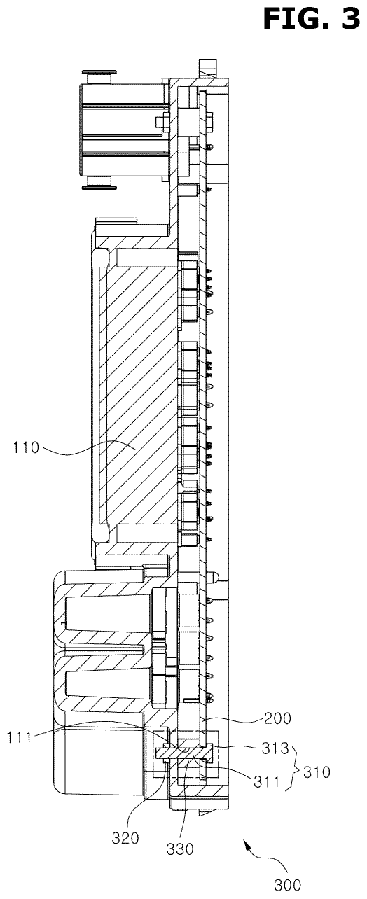

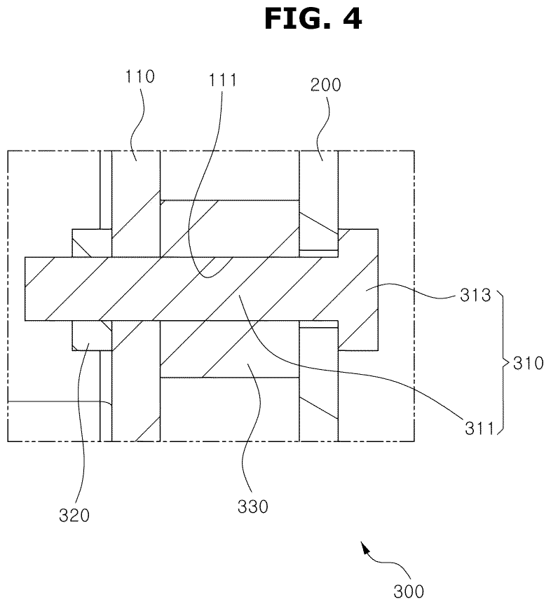

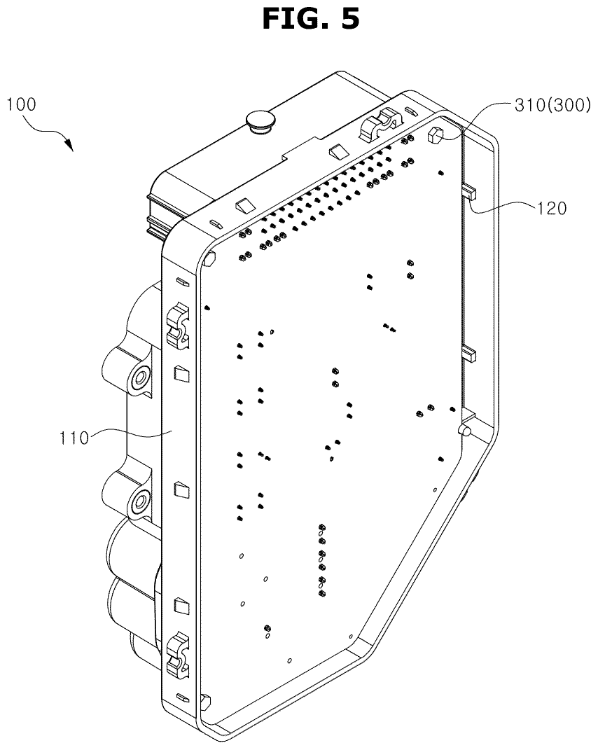

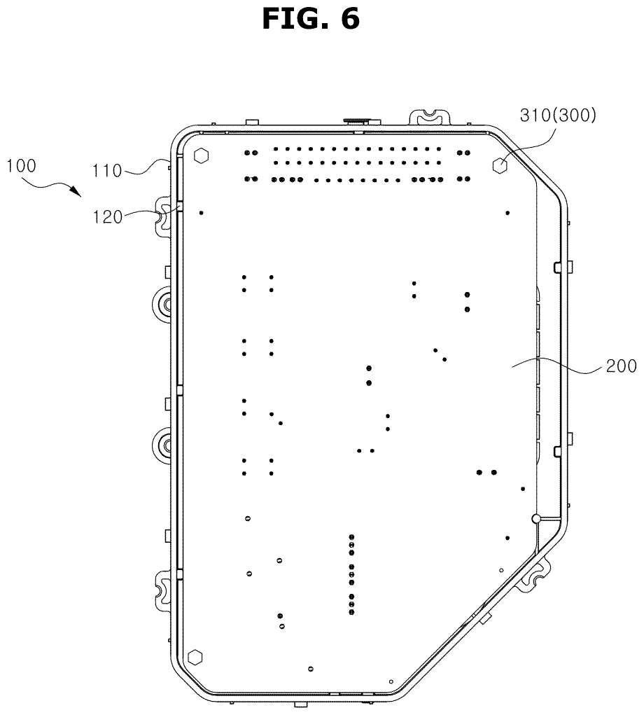

FIG. 1 is a perspective view schematically illustrating a noise reduction apparatus of an electronic brake device for a vehicle according to an embodiment of the present disclosure. FIG. 2 is an exploded perspective view schematically illustrating the noise reduction apparatus of an electronic brake device for a vehicle according to the embodiment of the present disclosure. FIG. 3 is a cross-sectional view taken along line A-A of FIG. 1. FIG. 4 is a partially enlarged cross-sectional view of region “B” of FIG. 3. FIG. 5 is a perspective view schematically illustrating a state in which a cover part is removed from the noise reduction apparatus of an electronic brake for a vehicle according to the embodiment of the present disclosure. FIG. 6 is a plan view schematically illustrating a state in which the cover part is removed from the noise reduction apparatus of an electronic brake for a vehicle according to the embodiment of the present disclosure.

Referring to FIGS. 1 to 6, the noise reduction apparatus of an electronic brake for a vehicle according to an embodiment of the present disclosure may include a housing 100, a printed circuit board (PCB) part 200, and a fastening part 300. One side (upper right side based on FIG. 2) of the housing 100 may be open. The housing 100 may accommodate the PCB part 200 therein. A cover part 400 described below may be mounted on the open housing 100.

The housing 100 may be installed in an electronic brake for a vehicle (not shown). The electronic brake may have a structure in which a hydraulic pressure is generated by operating a motor to generate a driver's required braking force. The electronic brake may be operated by circuit devices mounted on the PCB part 200.

The housing 100 may include a housing body 110 and housing inner protrusions 120. One side (upper right side based on FIG. 2) of the housing body 110 may be open. The housing body 110 may accommodate the PCB part 200 therein. The cover part 400 may be mounted on the opened housing body 110.

The housing 100 may further include a housing outer protrusion formed on an outer surface of the housing body 110. At least one housing outer protrusion may be disposed to protrude from the outer surface of the housing body 110. The housing outer protrusion formed to protrude from the outer surface of the housing body 110 may be detachably coupled to a cover ring formed on an edge portion of the cover part 400.

The housing body 110 may be provided with housing holes 111 into which bolt parts 310 of the fastening part 300 is inserted. The housing holes 111 may be formed to penetrate the housing body 110.

The housing inner protrusions 120 may be formed to protrude on the inner surface of the housing body 110 and come into contact with the edge portion of the PCB part 200. The housing inner protrusions 120 may come into contact with the edge portion of the PCB part 200 to prevent the PCB part 200 from being detached when the vehicle is driving, etc.

A plurality of housing inner protrusions 120 may be arranged at equal intervals on the inner surface of the housing body 110. The plurality of housing inner protrusions 120 may be arranged at equal intervals on the inner surface of the housing body 110 to secure points of contact with the PCB part 200 and prevent the PCB part 200 from receiving a large amount of load at a specific location.

The PCB part 200 may be mounted on the housing 100, and circuit devices may be arranged on the PCB part 200. As the circuit devices mounted on the PCB part 200, multilayer ceramic capacitor (MLCC) devices may be applied to assist current supply. The MLCC circuit devices may generate vibrations and may radiate high-frequency noises through the PCB part 200.

The PCB part 200 may be mounted on an electronic control unit (ECU) of the electronic brake for a vehicle. The PCB part 200 may be press-fitted to the ECU.

The edge portion of the PCB part 200 may be press-fitted to the housing inner protrusions 120. The edge portion of the PCB part 200 may be press-fitted to the housing inner protrusions 120. The PCB part 200 may be press-fitted to the housing inner protrusions 120, thereby reducing the vibrations of the PCB part 200 generated by the MLCC circuit devices.

The PCB part 200 may have holes formed therethrough corresponding to the housing holes 111 of the housing body 110. The bolt part 310 of the fastening part 300 may be inserted through the holes of the PCB 200.

The fastening part 300 can reduce vibration of the PCB 200 by fixing the PCB 200 to the housing 100. The PCB 200 is fixed to the housing 100 by the fastening part 300, thereby reducing vibration noise generated by MLCC circuit devices, etc.

The fastening part 300 may include bolts 310, nuts 320, and spacers 330.

The bolts 310 may be inserted into the PCB part 200 and the housing body 110. Each of the bolts 310 may include a bolt thread 311 and a head 313. The bolt thread 311 may be formed in a rod shape to be inserted into the PCB part 200 and the housing body 110 of the housing 100.

The bolt thread 311 may have screw threads formed on the outside thereof. The bolt thread 311 may have one end (left end based on FIGS. 3 and 4) exposed from the housing body 110. The exposed end of the bolt thread 311 may be screw-fastened to the nut 320.

The head 313 may be formed on the other end of the bolt thread 311 and have an outer diameter larger than the outer diameter of the bolt thread 311.

The heads 313 of the bolts 310 may be in close contact with the PCB part 200. The heads 313 of the bolts 310 may be in close contact with the PCB part 200 to prevent gaps between the heads 313 and the PCB part 200, thereby reducing vibration noise generated by the gaps.

Each of the nuts 320 may be coupled to one end (left end based on FIGS. 3 and 4) of each of the bolts 310, exposed to the outside of the housing body 110. A screw thread corresponding to the screw thread of the bolt thread 311 of the bolt 310 may be formed on an inner surface of the nut 320.

The nut 320 may be screw-fastened to the end of the bolt thread 311 of the bolt 310. The nut 320 may be screw-fastened to the end of the bolt thread 311, and may be maintained in a state of being firmly fastened to the bolt thread 311 from vibrations of the vehicle, etc.

One side (right side based on FIG. 4) of each of the nuts 320 may be in close contact with the housing body 110. The nuts 320 may be in close contact with the housing body 110 to prevent gaps between the nuts 320 and the housing body 110, thereby reducing vibration noise caused by the gaps.

The spacers 330 may be interposed between the PCB part 200 and the housing body 110 to separate the PCB part 200 and the housing body 110 from each other. The spacers 330 may separate the PCB part 200 and the housing body 110 from each other to prevent vibration of the PCB part 200 from being transmitted to the housing body 110.

Each of the spacers 330 may be formed in a hollow shape, and the bolts 310 may be inserted into the spacers 330. Each of the spacers 330 may be formed in a column shape with a hollow center. The bolt thread 311 of the bolt 310 may be inserted into the hollow center of the spacer 330.

A height of each of the spacers 330 may be set to be the same as the distance between the housing body 110 and the PCB part 200. One side (left side based on FIG. 4) of the spacer 330 may be in contact with the housing body 110, and the other side (right side based on FIG. 4) may be in contact with the PCB part 200.

The spacers 330 may be elastically deformable to absorb the vibration of the PCB part 200. The spacers 330 may be elastically deformable and may be springs. Alternatively, the spacers 330 may be formed of an elastically deformable rubber, silicone, or plastic material. The spacers 330 may absorb the vibration noise of the PCB part 200 while being elastically deformed and prevent the vibration noise of the PCB part 200 from being transferred to the housing body 110.

The noise reduction device of an electronic brake for a vehicle according to the present disclosure may further include the cover part 400. The cover part 400 may cover the PCB part 200 and close the open housing 100.

The cover part 400 can close the open housing 100 to prevent the vibration noise of the PCB part 200 installed in the housing 100 from being exposed to the outside.

The cover part 400 may be provided with a cover ring that is detachably coupled to the housing outer protrusion of the housing 100 on the edge portion thereof. The cover ring may be formed in a hollow shape to be inserted into the housing outer protrusion of the housing 100.

Only one side of the cover ring may be fixed to the edge portion of the cover part 400, and the other side of the cover ring may form a free end. Accordingly, the cover ring may be elastically deformably mounted on the housing body 110 of the housing 100.

The cover part 400 may be formed of a material that shields the vibration noise of the circuit devices of the PCB part 200. The cover 400 may be formed of a material that shields the vibration noise of the circuit devices of the PCB 200, and may include plastic, rubber, etc.

The assembly process of the noise reduction device of an electronic brake for a vehicle according to the present disclosure is explained.

The PCB part 200 may be mounted on the housing inner protrusions 120 of the housing 100. Before the PCB part 200 is mounted on the housing 100, the spacers 330 of the fastening part 300 may be interposed between the PCB part 200 and the housing body 110.

The bolts 310 of the fastening part 300 may be inserted into the PCB part 200 and the housing body 110. The heads 313 of the bolts 310 may be in close contact with the PCB part 200.

The PCB part 200 may be press-fitted to the housing inner protrusions 120. The PCB part 200 may be press-fitted to the housing inner protrusions 120 to prevent detachment and prevent vibration noise due to separation.

The nuts 320 may be screw-fastened to the bolt threads 311 of the bolts 310. The nuts 320 may be closely attached to the housing body 110.

The cover part 400 may close the open housing 100 to prevent the vibration noise generated from the PCB part 200 from being exposed to the outside.

According to the noise reduction device of an electronic brake for a vehicle according to the present disclosure, the vibration noise generated from a plurality of circuit devices mounted on a PCB part can be reduced, thereby reducing discomfort to passengers riding in the vehicle due to the vibration noise.

In addition, according to the present disclosure, it is possible to prevent quality deterioration by reducing the vibration noise generated from the electronic brake.

Although exemplary embodiments of the disclosure have been disclosed for illustrative purposes, those skilled in the art will appreciate that various modifications, additions and substitutions are possible, without departing from the scope and spirit of the disclosure as defined in the accompanying claims. Thus, the true technical scope of the disclosure should be defined by the following claims.

What is claimed is:

1. A noise reduction device of an electronic brake for a vehicle, the noise reduction device comprising:
a housing;
a printed circuit board (PCB) part installed in the housing and including circuit devices disposed thereon; and
a fastening part configured to fasten the PCB part to the housing to reduce vibration of the PCB part.

2. The noise reduction device of claim 1, wherein the housing comprises:
a housing body configured to accommodate the PCB part; and
housing inner protrusions protruding on an inner surface of the housing body and in contact with an edge portion of the PCB part.

3. The noise reduction device of claim 2, wherein the edge portion of the PCB part is press-fitted to the housing inner protrusions.

4. The noise reduction device of claim 2, wherein the fastening part comprises:
bolts inserted into the PCB part and the housing body;
nuts coupled to the bolts, each nut coupled to an end of each of the bolts exposed to the outside of the housing body; and
spacers interposed between the PCB part and the housing body to separate the PCB part and the housing body from each other.

5. The noise reduction device of claim 4, wherein each of the spacers is formed in a hollow shape, the bolt being inserted into the spacers.

6. The noise reduction device of claim 4, wherein the spacers are elastically deformable to absorb the vibration of the PCB part.

7. The noise reduction device of claim 4, wherein each nut is screw-fastened to the end of each of the bolts.

8. The noise reduction device of claim 4, wherein a head of each of the bolts is in close contact with the PCB part.

9. The noise reduction device of claim 4, wherein the nuts are in close contact with the housing body.

10. The noise reduction device of claim 1, further comprising a cover part configured to cover the PCB part and close the open housing.
